(19) United States
(12) Patent Application Publication
(10) Pub. No.: US 2025/0372481 A1
(43) Pub. Date: Dec. 4, 2025

(54) METHODS AND APPARATUS FOR COOLING DIE STACKS

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US)

(21) Appl. No.: 18/745,272

(22) Filed: Jun. 17, 2024

Related U.S. Application Data
(60) Provisional application No. 63/653,448, filed on May 30, 2024.

(51) Int. Cl. H01L 23/427; H01L 21/48; H01L 23/00; H01L 23/373; H01L 23/48; H01L 25/065

(52) U.S. Cl. CPC H01L 23/427; H01L 21/4882; H01L 23/3738; H01L 23/481; H01L 24/05; H01L 24/08; H01L 24/80; H01L 25/0657; H01L 2224/05006; H01L 2224/05012; H01L 2224/05017; H01L 2224/05018; H01L 2224/05546; H01L 2224/05557; H01L 2224/05558; H01L 2224/08145; H01L 2224/80895; H01L 2224/80896; H01L 2225/06541; H01L 2225/06568; H01L 2225/06589; H01L 2924/3011; H01L 2924/381

(57) ABSTRACT

An electronics package can comprise a first die, a cooling element disposed over the first die, a second die disposed over the cooling element, and a plurality of vias extending through the cooling element from the first die to the second die. The cooling element can comprise at least one cavity. The at least one cavity can comprise a wicking layer disposed over an interior surface of the at least one cavity.

### CROSS-REFERENCE TO RELATED APPLICATIONS

This application claims priority to U.S. Provisional Application No. 63/653,448, filed May 30, 2024, titled “METHODS AND APPARATUS FOR COOLING DIE STACKS,” the disclosure of which is incorporated herein by reference in its entirety for all purposes.

### BACKGROUND

### Field

The field relates to dissipating heat in microelectronic devices, including microelectronic devices having stacked active dies.

### Description of the Related Art

Integrated circuit design has long followed Moore's Law and packed more and more active devices into smaller footprints, thereby increasing circuit speed and reducing power consumption. However, as such scaling has approached physical limits, 2.5D and 3D packaging, including die stacking, has become more popular as a way of increasing performance beyond what critical dimension scaling alone can achieve. Such die stacking can include, for example, stacking dies of same or different functionalities (e.g., stacking of dynamic random-access memory (DRAM) dies to form high bandwidth memory stacks), disaggregation of circuit functionality into chiplets, and can include hybrid bonding for dense and short interconnections between dies.

Such approaches can raise new concerns. For example, it can be difficult to extract heat from multiple densely packed dies or stacked dies in advanced packages. While stacking dies can be beneficial for numerous reasons, including optimized space utility within the device package and increased device performance, a continuing need exists for cooling devices that can support stacked die structures and enable the formation of high density, fine pitch interconnects with low impedance.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A is a schematic side sectional view of stacked dies including a heat pipe element including a plurality of interconnects, taken along a length of a heat pipe cavity or channel, according to one embodiment.

FIG. 1B is a schematic cross-sectional view of the heat pipe element illustrated in FIG. 1A, taken transverse to a plurality of heat pipe segments, according to one embodiment.

FIG. 2 is a schematic cross-sectional view of a heat pipe element, including a plurality of interconnects, according to one embodiment.

FIGS. 3A-3G are schematic cross sections illustrating an example process for forming a heat pipe element according to some embodiments.

FIG. 4A is a schematic cross section illustrating an example die stack embodiment including a plurality of heat pipe elements, according to one embodiment.

FIG. 4B is a close-up view of a portion of the die stack of FIG. 4A.

FIG. 5 is a schematic cross section illustrating an example die stack embodiment including a heat pipe element, a connected expansion chamber, and a heat sink disposed over the die stack.

FIGS. 6A-6D are schematic illustrations of heat pipe elements according to some embodiments. FIG. 6A is a schematic side sectional view of a heat pipe element, according to one embodiment. FIG. 6B is a schematic cross-sectional view taken along lines 6B-6B of FIG. 6A, according to one embodiment, illustrating an open cavity with multiple pillars housing interconnects. FIG. 6C is a similar schematic cross-sectional view of a heat pipe element according to another embodiment, illustrating multiple heat pipe channels separated by straight walls housing interconnects. FIG. 6D is a similar schematic plan view of a heat pipe element according to still another embodiment, illustrating multiple heat pipe channels separated by serpentine walls housing interconnects.

FIGS. 7A-7B are schematic cross sections illustrating direct bonding of microelectronic elements, according to one embodiment.

Like reference numbers are used to refer to like features throughout the description and drawings.

### DETAILED DESCRIPTION

Although several embodiments, examples, and illustrations are disclosed below, it will be understood by those of ordinary skill in the art that the inventions described herein extend beyond the specifically disclosed embodiments, examples, and illustrations and include other uses of the inventions and obvious modifications and equivalents thereof. Embodiments of the inventions are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the inventions. In addition, embodiments of the inventions can comprise several novel features and no single feature is solely responsible for its desirable attributes or is essential to practicing the inventions herein described.

With the growing trend of miniaturization in microelectronics devices, the density of components included in these devices is increasing, furthering the need to efficiently package such devices. Another trend involves disaggregating circuits into chiplets for reaggregation by packaging. Memory chips (e.g. DRAM, NAND, etc.) are also trending to pack an increasingly higher density of memory within one die (e.g., 3D-NAND), and stack several dies within the same package (e.g., high bandwidth memory (HBM) stacks for DRAM) to provide maximum storage capacity as well as higher bandwidth. Accordingly, die stacking is becoming an important feature in the fabrication of microelectronics devices. However, die stacking presents several challenges, including higher impedances, which can accompany the fine pitch (e.g., edge-to-edge or center-to-center distances) interconnects between dies, and greater thermal generation, which comes with increases in power density.

In conventional die stacks, the bottommost die is generally the hottest die, and without proper heat dissipation, the device performance can decrease or fail entirely, possibly resulting in structural damage to the device. Specifically, as heat generating dies are stacked, a heat dissipating apparatus (e.g., heat spreader, heat pipe, etc.) can be disposed at the top of the die stack. A thermal interface material (TIM) can be provided on the topmost die and the heat dissipating apparatus can be in direct contact with this TIM. In this configuration, the topmost die can dissipate heat through the TIM coupled to the heat dissipating apparatus. However, the other dies lower in the stack (e.g., middle and bottom dies) may fare poorly. These dies, especially the dies located towards the bottom of the stack, generate and dissipate heat through one or more of the dies stacked above them. The inefficiency of this dissipation process can result in heat being trapped in the middle and bottom dies. Further, when one of the middle or bottom dies has increased heat generation, the heat dissipation issue can worsen. One such configuration where this could happen would involve a die stack having a logic die at the bottom of the stack.

To better address the heat generated from dies lower in a die stack, a heat dissipation element sandwiched between the dies is desirable. For example, cooling devices can be positioned between a lower die and a heat sink. A cooling approach that utilizes a cooling element integrated between dies within a die stack can be more effective. For example, one cooling approach can include a liquid cooled device (e.g., liquid cooled cavities within the sandwiched die) in which the liquid cooling channels require a relatively high thickness compared to die thicknesses (e.g., 100 μm or higher) to maintain an acceptable liquid pressure and be operative. Although liquid cooling channels can improve heat dissipation from lower dies in the die stack, the thickness of the liquid cooling channels impedes fabricating shallow interconnects having a fine pitch, thereby limiting the ability to achieve high density interconnects for die stacking with cooling in between the dies. The height requirements of liquid cooling channels can also substantially increase electrical path lengths through the elements housing the channels, which would increase the impedance and latency. The interconnects used in the cooling element could be through silicon vias (TSVs) that would need to be taller than the channel heights (e.g., greater than 100 μm), which is expensive and pitch limiting, due to the limited high aspect ratios (e.g., <10:1) of commercially available TSV processes.

A cooling element capable of facilitating heat removal from lower dies in a die stack while allowing for a high density of fine pitch interconnects is desired. Such an element could be a thin thermal extraction and evacuation device, such as a very thin heat pipe element, positioned between dies. Heat pipes are closed, elongate structures that move liquid from a condensation (e.g., cool) zone to a vaporizing (e.g., hot) zone. Heat is generated by the active devices to be cooled and contacts the hot zone of the heat pipe. The liquid in the heat pipe is heated and transitions to a vapor; the vapor moves from the hot zone to a cool zone and condenses, and the condensed fluid can be transported via a wicking media from the cool zone to the hot zone of the heat pipe along the interior of the heat pipe. By making the heat pipe very thin, the electrical interconnects therethrough can be relatively short to minimize losses due to impedance along the electrical path. Efficient wicking material should have good thermal conductivity to transport heat from heat source to cooling liquid; support the capillary action to transfer the condensed liquid back to the heat source; and have the capability to resist the high temperatures involved. The wicking media can include homogenous wicking media such as metal fibers (e.g., fibers made from metals such as copper, aluminum, nickel, stainless steel, titanium, metal alloys, etc.), porous metals (e.g., porous copper), wire meshes (e.g., core wires), glass fibers, woven cloths, or composite wicking media.

Various embodiments disclosed herein relate to a wafer-based (e.g., Si, glass, ceramic, quartz, etc.) heat pipe solution. A monolithic or solid-state cooling element (e.g., a semiconductor element) can be fabricated using semiconductor fabrication techniques, and can thereby be made thin enough to facilitate integration between dies of a stack. In some embodiments, an integrated device package can include a cooling element between two or more active dies and the cooling element can include an embedded heat pipe segment and pillar or wall structures through which a plurality of interconnects or TSVs can extend, facilitating an electrical connection between dies on opposing sides of the cooling element. One die can be a processor die and the other die can be a memory die. In other embodiments, the cooling element can be used between two memory dies (e.g., between memory dies within HBM stacks or between the core/logic die at the bottom and a memory die within HBM stacks). In some other embodiments, the cooling element can be used between two processor dies (e.g., CPU, GPU, MCU, NPU, DPU, etc.). In some embodiments, the cooling element is directly bonded to the adjacent dies to ensure excellent thermal contact. In yet other embodiments, an integrated device package can include a plurality of cooling elements sandwiched between dies of a stack of dies.

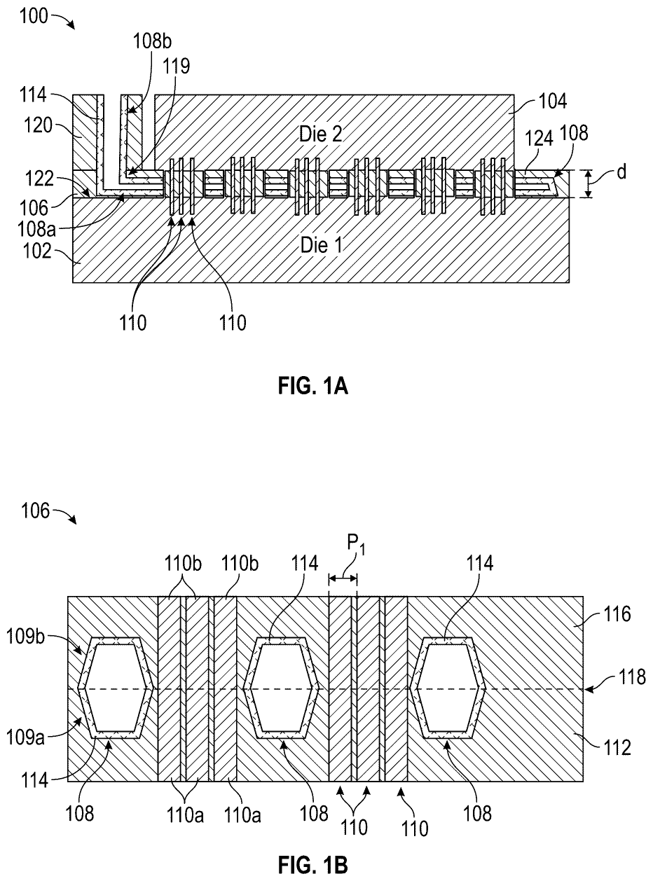

FIG. 1A illustrates an electronics package (e.g., cooling electronics package) 100 comprising a first die 102 and a second die 104 disposed over the first die 102. The electronics package 100 further includes a cooling element 106 (e.g., a semiconductor element), also referred to herein as a heat pipe element, disposed over the first die 102 and below the second die 104. The cooling element 106 can have at least one cavity 108 or heat pipe segment for transferring heat generated from at least the first die 102 to outside of the electronics package 100. For example, in FIG. 1B, a cross-sectional view is provided showing a cooling element 106 having three cavities 108 (e.g., channels) or heat pipe segments and a plurality of interconnects 110 distributed between the cavities. Although three cavities are illustrated, fewer or greater than three cavities or channels can be formed within the cooling element 106. The presence of multiple cavities within the cooling element can more efficiently facilitate heat removal from the surface of a lower, heat generating die. The cooling element 106 can be formed using modular components that are directly bonded to one another. As shown in FIG. 1B, the cooling element 106 is formed by bonding, and particularly hybrid bonding, a first substrate 112 having etched trenches 109a comprising wicking layers 114 and a first plurality of interconnects 110a with a second substrate 116 having etched trenches 109b comprising wicking layers 114 and a second plurality of interconnects 110b at a bonding interface 118.

In some embodiments, the heat pipe element (or cooling element 106) is an enclosed (e.g., sealed), elongate structure. In some embodiments, and as shown in FIG. 1A, the cooling element 106 can be an enclosed, elongate structure including one or more bends 119. For example, the electronics package 100 can include a dummy die 120 disposed over an end of the cooling element 106. In this configuration, the electronics package 100 can include a first cavity 108a disposed over and extending in proximity to an upper surface 122 of the first die 102, a second cavity 108b (e.g., a connecting cavity) that is coupled to and in fluid communication with the first cavity 108a, and a wicking layer 114 on the inner surfaces of both cavities 108a, 108b. The second cavity 108b extends from the cooling element 106 through the dummy die 120 and is approximately perpendicular to the first cavity 108a. Although the bend 119 is described to be in the heat pipe element (e.g., cooling element 106) in this example, in other embodiments, the bend of the heat pipe can be in the dummy die in other arrangements. For example, the second cavity in the dummy die can have a first portion and a second portion, such that the first portion extends from the first die through the dummy die disposed over the first die, and the second portion is approximately perpendicular to the first portion and in fluid communication with the first cavity. In this configuration, the bend is located within the dummy die.

In some embodiments, the heat pipe element (e.g., cooling element 106) can have two or more bends. In some embodiments, the heat pipe element can have no bends. The inclusion of bends within the heat pipe, whether or not included within the heat pipe element, enables the device to carry heat generated by lower dies within a die stack to a location outside of the die stack. The bends in the heat pipe can allow the heat waste to be transferred to a heat dissipation element disposed over the die stack.

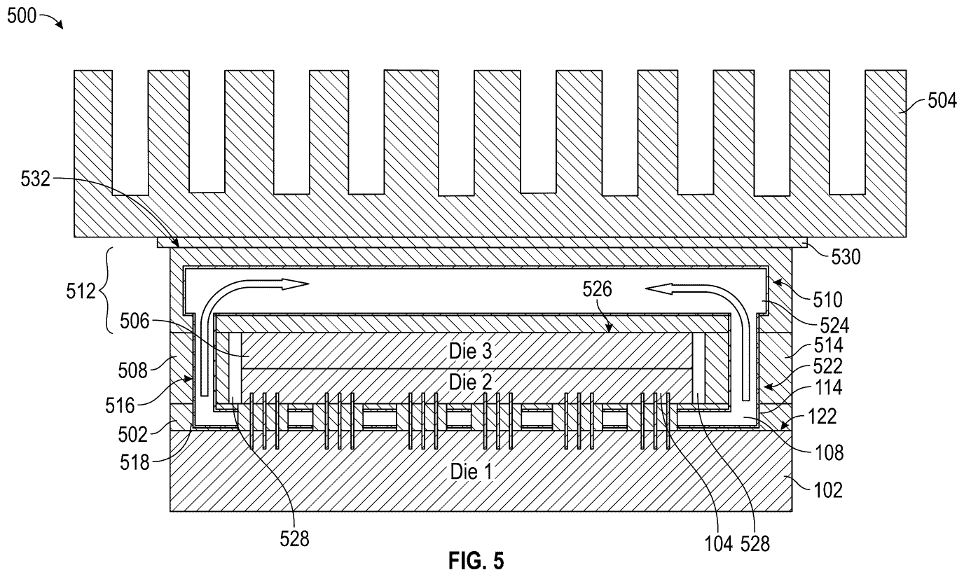

The electronics package 100 further comprises an upper cooling element 512 (see FIG. 5) disposed over the second die 104. The upper cooling element 512 can include an expansion chamber 510 (see FIG. 5) that is in fluid communication with at least the second cavity. The expansion chamber 510 completes the closed loop facilitating the operation of the heat pipe element 106. In some embodiments, this closed loop is sealed (e.g., hermetically sealed). In some embodiments, the closed loop undergoes vacuum pulling prior to the completion of the packaging (e.g., the vacuum pressure can be approximately 0.05-0.5 Torr), which can help improve or enhance performance of the heat pipe element. A heat sink can be disposed over and coupled to the upper cooling element to remove heat away from the electronics package 100. In some embodiments, the cooling element between the first and second dies is in fluid connection with the expansion chamber in the upper cooling element via one pathway through one dummy die. In some embodiments, the cooling element between the first and second dies is in fluid connection with the expansion chamber in the upper cooling element via one of at least two pathways (each pathway going through one of two dummy dies).

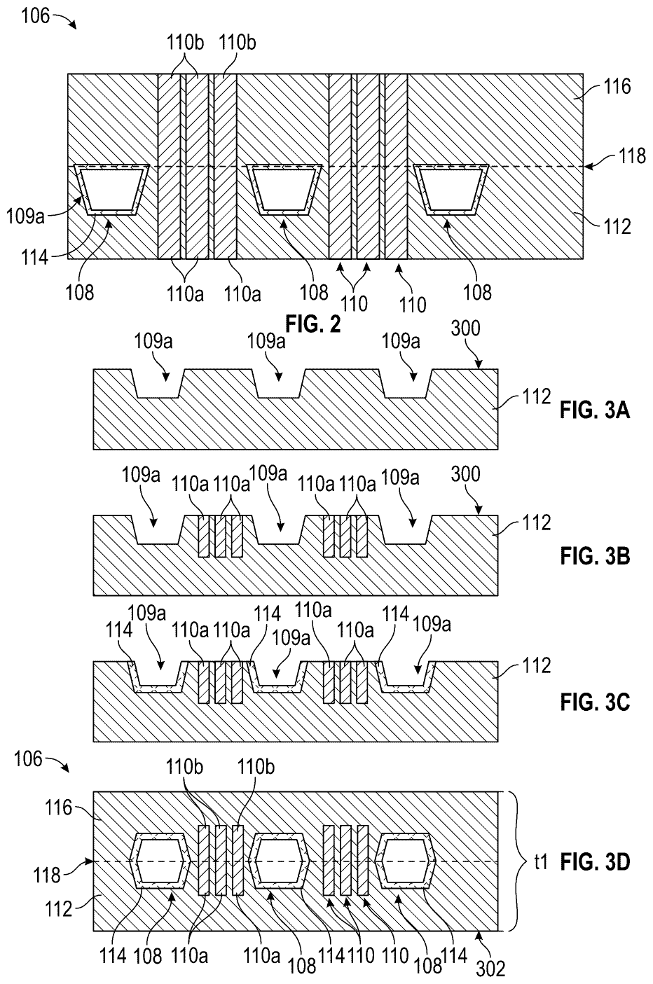

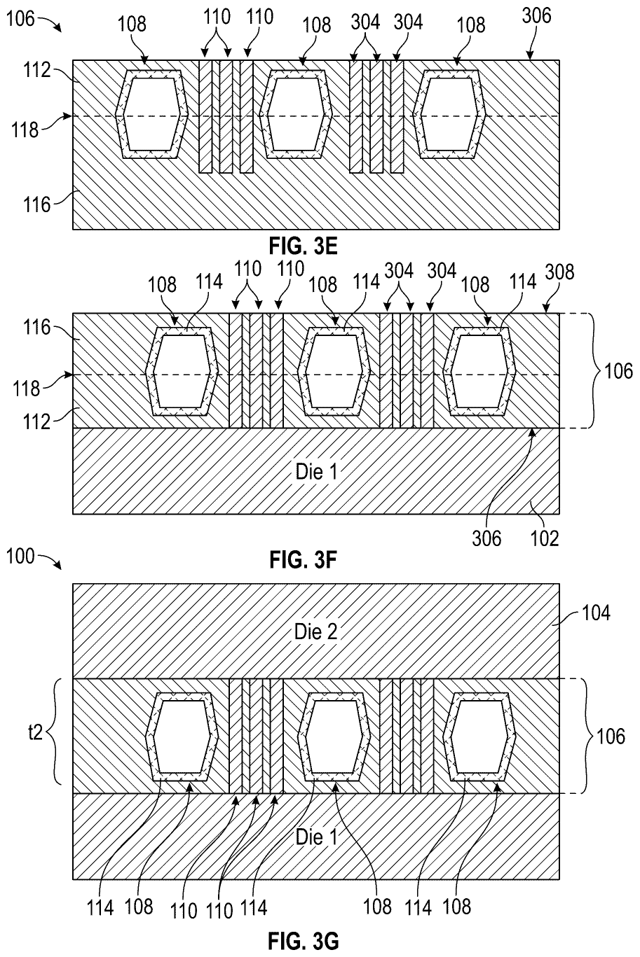

As described below with respect to FIGS. 3A-3G, the cavity 108 in the cooling element or heat pipe element 106 can be formed in a substrate material 124 (e.g., silicon) through an etching process. For example, an etching process can be used to etch a first trench 109a into the first substrate 112 and a second trench 109b into the second substrate 116 such that the first trench 109a and the second trench 109b form a cavity 108, such as the illustrated channel, when the first substrate 112 and the second substrate 116 are bonded together. The etching process can include a wet etching process (e.g., isotropic, anisotropic, or partially anisotropic wet etching process). In some embodiments, the etching process can include a dry etching process (e.g., reactive ion etching (RIE)). In some embodiments, the cavity 108 can have a cross-sectional shape that is approximately hexagonal, which would have greater surface area to pull heat from the surrounding substrate (e.g., silicon), as compared to a cavity comprising a shape such as a rectangular prism. In some embodiments, and as shown in FIG. 2, the cavity 108 can have an approximately trapezoidal cross-section shape. In some embodiments, the cavity 108 can have an approximately triangular cross-section shape. For example, the first substrate 112 and the second substrate 116 can be bonded to each other, and the cavity 108 formed is a result of the trenches 109a, 109b etched into the first and second substrates 112, 116, respectively. In some embodiments, the first substrate 112 and the second substrate 116 can be bonded to each other, and the cavity 108 formed is a result of the trenches formed or etched into only one of the first and second substrates 112, 116.

The wicking layer 114 is disposed over a surface of the cavity 108. The wicking layer 114 can be approximately 1 μm to approximately 5 μm thick. In some embodiments, the wicking layer 114 can be less than approximately 1 μm in thickness. In some embodiments, the wicking layer 114 can be in a range of approximately 0.1 μm up to the thickness of the cavity 108 itself (i.e., filling the cavity 108). In some embodiments, the wicking layer 114 can be greater than approximately 5 μm thick. In some embodiments, the wicking layer 114 can have a thickness approaching approximately half the thickness of the heat pipe element 106. In some embodiments, the wicking layer 114 comprises an etched surface (e.g., non-smooth surface) of the cavity 108, capable of facilitating the transport of a fluid in the heat pipe element. In some embodiments, the etched surface can have a roughness between approximately 0.1 μm and a value approximately equal to a thickness of the wicking layer 114. In some embodiments, the wicking layer 114 can be grown on a surface of the cavity 108. Still, in some embodiments, the wicking layer 114 can be formed through a deposition process. The wicking layer 114 can be a mesh material (e.g., mesh Cu), a porous material, a fibrous or dendritic material, metal wires, a sintered material, etc. In some embodiments, the wicking material (as described herein) can comprise a metal or a plastic. In some embodiments, the wicking material or media can include homogenous wicking media such as metal fibers (e.g., fibers made from metals such as copper, aluminum, nickel, stainless steel, titanium, metal alloys, etc.), porous metals (e.g., porous copper), wire meshes (e.g., core wires), glass fibers, woven cloths, or composite wicking media. Such porous or fibrous materials can serve the wicking functions as a wall lining layer or through completely filling the cavity 108. The wicking layer 114 allows the fluid to move between an evaporator section and a condenser section of the heat pipe through capillary action. The fluid can be any suitable phase change fluid for heat pipe cooling of dies within a microelectronic assembly. For example, the fluid could be water, distilled water, water mixed with a surfactant, water mixed with another fluid for improved viscosity management, etc. In some embodiments, the fluid can be a low evaporating temperature (e.g., 60° C.) fluid. In some applications, other fluids such as glycol, ammonia, acetone, and/or methanol can also be used. In some embodiments, the fluid can be a liquid that evaporates at a temperature between approximately 50° C. and approximately 150° C. In some embodiments, the cavity is vacuum sealed to extract better performance with a vacuum pressure of about 0.05-0.5 Torr.

In some embodiments, the cooling element 106 can have a thermal conductivity greater than that of the dies 102, 104 adjacent to the cooling element 106. For example, the cooling element 106 can have a thermal conductivity greater than or approximately equal to that of the first die 102 disposed below the cooling element 106 and greater than that of the second die 104 disposed over the cooling element 106. For example, the first and second substrates 112, 116 of the cooling element 106 can comprise silicon. Such a configuration allows for heat generated by the first and second dies 102, 104 to propagate through the cooling element 106 to reach the cavity 108 that serves as a heat pipe segment. The materials for the first and second substrates 112, 116 that comprise the cooling element 106 can be different materials. In some embodiments, the first substrate 112 of the cooling element 106 can have a first thermal conductivity and the second substrate 116 of the cooling element 106 can have a second thermal conductivity. In some embodiments, the first thermal conductivity can be greater than the second thermal conductivity. For example, the first substrate 112 can comprise silicon and the second substrate 116 can comprise glass. The cooling element 106 has the benefit of being customizable to optimally suit the heat removal needs of the integrated die stack of the electronics package 100. The cooling element 106 can be fabricated to focus on heat removal from the first die 102 (e.g., lower die) of the die stack, or the cooling element 106 can be fabricated to ensure heat removal from both the first die 102 (e.g., lower die) and the second die 104 (e.g., die disposed over the cooling element).

The cooling element 106 can be fabricated to be a thin element. In some embodiments, the cooling element 106 can have a thickness d between approximately 5 μm to approximately 100 μm. For example, the cooling element 106 can have a thickness of approximately 5-80 μm, approximately 10-70 μm, approximately 20-50 μm, or it can have a thickness equal to or less than the thickness of a die 102 or 104 in the die stack of the electronics package 100 (e.g., approximately 35 μm to approximately 40 μm, or approximately 50 μm). The thinness of the cooling element 106 makes possible the inclusion of vertically short and fine pitch interconnects, as they can be formed in relatively low aspect ratio vias, which can mean increased functionality. The electronics package 100 comprises a plurality of fine pitch interconnects or TSVs 110, which can connect various routing layers (e.g., redistribution layers (RDLs)) within the electronics package 100. In some embodiments, one or more routing layers can be disposed on the top, or bottom, or one or more sides of the cooling element 106. In some embodiments one or more RDL or routing layers can be located at the bonding interface 118 (e.g., hybrid bonding interface) of the first and second substrates 112, 116. The TSVs 110 extend through the cooling element 106 and couple the first and the second dies 102, 104. In some embodiments, the TSVs 110 can comprise power/ground TSVs, signal TSVs, and/or thermal TSVs. In some embodiments, the TSVs 110 electrically connect the first and the second dies 102, 104. The TSVs 110 can also aid in thermal transfer from a hotter die to a cooler die. The pitch p1 of the interconnects can be in a range of 1 μm to 200 μm.

FIGS. 3A-3G illustrate an example process for forming the electronics package 100, including a heat pipe device, according to some embodiments. FIGS. 3A-3D show stages for fabricating a cooling element 106 including heat pipe segments. In some embodiments, the heat pipe segments can have a cross-sectional area of between approximately 2.5 μm² and 2.0 mm². In some embodiments, the heat pipe segments can have a cross-sectional area between approximately 5.0 μm² and 0.4 mm². In some embodiments, the cross-sectional areas refer to the total cross-sectional area of the heat pipe segment(s) in the cooling element and exclude larger cross-sections that may be located elsewhere in the heat pipe (e.g., the total cross-sectional area does not include the cross section of the expansion chamber 510 (see FIG. 5)). In some embodiments, the cross-sectional areas can refer to the cross-sectional area of an individual heat pipe segment. In FIG. 3A, the first substrate 112 is etched (e.g., wet or dry etching) to form one or more trenches 109a on a surface 300 of the first substrate 112. A plurality of TSVs 110a can be formed in the first substrate 112. The TSVs 110a can extend from the same surface 300 which underwent the etching process to form trenches 109a through at least a portion of the first substrate 112. In some embodiments, one or more routing layers along with a separate hybrid bonding layer may also be formed on the same side of surface 300. In some embodiments, the TSVs 110a and one or more routing layers and/or a separate hybrid bonding layer (not shown) can be fabricated first, and the trenches 109a subsequently etched into the first substrate 112. In the illustrated sequence, the trenches can be formed first and covered during subsequent formation of TSVs. The wicking layer 114 can be formed by texturing the surface of the cavity 108 itself, by depositing material on the surface of the cavity 108 (e.g., deposit a mesh layer, porous material, etc.) or by growing material on the surface of the cavity 108 (e.g., dendritic material, fibrous material, metal wires, etc.). FIG. 3C shows the wicking layer 114 formed on the trenches 109a. The process depicted in FIGS. 3A-3C can be repeated on the second substrate 116. Routing layers or RDL layers can be formed only on one or both substrates. As shown in FIG. 3D, the first substrate 112 and the second substrate 116 can be bonded together at the bonding interface 118 (e.g., directly bonded, particularly hybrid bonded) to form the cooling element 106 having a thickness t1. This bonding step results in the formation of the cavity or cavities 108 and additionally includes the bonding of the TSVs 110a, 110b in the first and second substrates 112, 116. At the junctions of the trenches along the bonding interface 118, the wicking layer or surface 114 of the first substrate 112 and the wicking layer or surface 114 of the second substrate 116 are brought close enough to one other such that any existing gaps can be bridged by capillary action.

FIGS. 3E-3G show stages for integrating the cooling element 106 into a die stack. After the first and second substrates 112, 116 are bonded, the bonded structure 106 can be thinned on a first side 302 until the TSV ends 304 are exposed, as shown in FIG. 3E. The thinning can include grinding, lapping, and/or chemical mechanical polishing (CMP) or any other suitable approach as is known in the art for removing this layer of material. In some embodiments, once the TSV ends 304 are exposed, one or more routing layers (e.g., RDLs) and/or a separate hybrid bonding layer or hybrid bond pads (routing and pads not shown) can be formed.

As shown in FIG. 3F, the cooling element 106, having a first planarized surface 306, is bonded (e.g., directly bonded, particularly hybrid bonded) to a first die 102. A second planarized surface 308 is formed (e.g., by grinding, lapping, and/or CMP) on the side of the cooling element 106 that opposes the first die 102, exposing the TSV ends 304. This second side 308 is then bonded (e.g., directly bonded, particularly hybrid bonded) to the second die 104, as shown in FIG. 3G. The resulting cooling element 106 is disposed between the first and second dies 102, 104 and can have a thickness t2. The thickness t2 is less than the thickness t1 (FIG. 3D), and t2 can be between approximately 10 μm to approximately 100 μm. Although the cavities 108 are illustrated as having hexagonal cross-sections, which can result from wet etching single-crystal silicon substrates, the cavities 108 can include other shapes. The resulting heat pipe element from these formation steps is a device having a monolithic structure that is fabricated using solid state or semiconductor-like fabrication processes. The heat pipe element can be fabricated using silicon (e.g., single crystal silicon).

In some embodiments, instead of repeating the trench formation process depicted in FIGS. 3A-3C on the second substrate 116, the prepared first substrate 112 (e.g., the first substrate 112 having etched trenches 109a and interconnects 110a) can be bonded to the second substrate 116 having TSVs extending through the second substrate 116 as illustrated in FIG. 2. The steps illustrated in FIGS. 3E-3G can be repeated on this bonded structure. In this embodiment, the fabrication steps are simplified through omitting the trench etching in a second substrate.

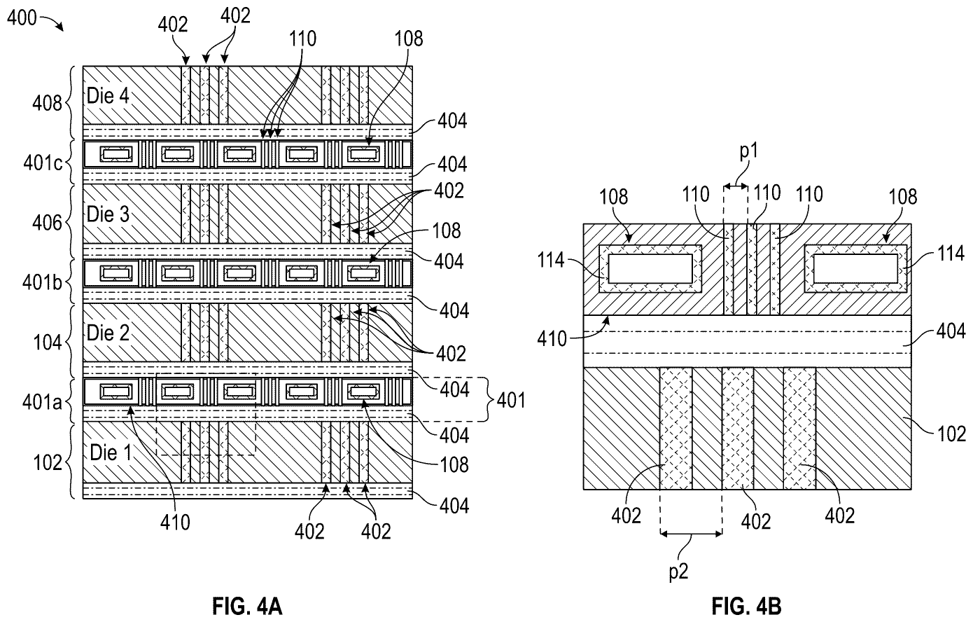

FIG. 4 illustrates a die stack 400 having a plurality of cooling elements 401a-401c, each including heat pipe segment(s). A magnified view of the region of the die stack 400 denoted by the dashed outline is additionally provided. In one embodiment, the die stack 400 can include a first active die 102 having a plurality of contacts (shown as TSVs 402) having a pitch, p2, and at least one RDL 404. A first cooling element 401a including a first plurality of fine pitch TSVs 110 having a pitch, p1, can be disposed over the first die 102. The pitch p1 can be less than the pitch p2, and in some embodiments, p1 can have values in the range of approximately 20%-200% of the pitch p2. A second die 104 having a plurality of TSVs 402 and at least one RDL 404 can be disposed over the first cooling element 401a and the first die 102. The die stack 400 can include a second cooling element 401b including a second plurality of fine pitch TSVs 110, wherein the second cooling element 401b is disposed over the second die 104. A third die 406 can be disposed over the second cooling element 401b and include at least one RDL 404 and a plurality of TSVs 402. A third cooling element 401c including a third plurality of TSVs 110 can be disposed over the third die 406. A fourth die 408 having at least one RDL 404 and a plurality of TSVs 402 can be disposed over the third cooling element 401c. In some examples, the plurality of heat pipe elements is in fluid communication with one another (e.g., the first cooling element 401a is in fluid communication with the second cooling element 401b, and the second heat pipe element is in fluid communication with the third cooling element 401c) by way of adjacent elements (not shown) similar to the dummy die 120 described above. In other embodiments, each cooling element forms its own independent heat pipe circuit by way of adjacent element.

The dies 102, 104, 406, and 408 can be electrically connected to one another through the plurality of TSVs 402, 110 extending through the cooling elements 401a-c and any intervening RDL layers 404, where the RDL layers can be disposed on the dies, or the cooling elements, or both. For example, the TSVs 402 in the first die 102 extend through the first die 102 and contact the RDL layer 404. The RDL layers 404 provide pathways for the signal, power, ground, etc. to the TSVs 110 in the cooling element 401 (e.g., first cooling element 401a) to the extent the contacts of adjacent dies and cooling elements are not aligned. In some embodiments, the cooling elements 401a-c can include RDL layers 404. For example, an RDL layer 404 can be formed on a bottom surface 410 of the cooling element 401a. In some embodiments, each cooling element 401a-401c can be sandwiched between two of the dies 102, 104, 406, and 408. In some embodiments, a cooling device (including heat pipe segment(s)) can be integrated between certain dies, but not necessarily be included between every die in the die stack. For example, the die stack embodiment could include a single heat pipe element, which can be sandwiched between two dies within the die stack (e.g., the first die 102 and the second die 104). In another example, the die stack embodiment could include two heat pipe elements, where a first heat pipe element is sandwiched between the first and the second die, and a second heat pipe element is sandwiched between the second and the third die, or between the third and the fourth die. Alternatively, the first heat pipe element can be sandwiched between the second and the third die and the second heat pipe element can be sandwiched between the third and the fourth die.

Although a heat pipe element, which can also be described as a wicking cavity device, is preferably positioned between dies nearer to the bottom of a die stack where heat dissipation may present greater problems, in some embodiments, the heat pipe element can be positioned nearer to the top of a die stack. The flexibility of placement of the heat pipe element in the integrated device stacks enables improved and customizable thermal management of such systems while allowing for increased functionality of the devices through the increased density of fine-pitched interconnects. In some embodiments, one or more interposers can be included within the integrated die stack to facilitate the electrical connection between the dies and the heat pipe elements. Further, although not shown, the heat pipe elements can be coupled to additional elements that aid in removing heat from the die stack. For example, the heat pipe elements can be coupled to heat sinks. In some embodiments, the heat sink can be disposed over the uppermost die of the die stack.

FIG. 5 illustrates an example die stack 500 having a cooling element in the form of a heat pipe element 502 and a heat sink 504. In the embodiment shown, the die stack 500 includes the first die 102, a heat pipe element 502 disposed over the first die 102, the second die 104 disposed over the heat pipe element 502, and a third die 506 disposed over the second die 104. The dies 102, 104, 506 can be directly bonded, particularly hybrid bonded, to other dies or to the heat pipe element in order to minimize thermal resistance at the interfaces.

A first dummy die 508 is disposed over the first die 102 adjacent an outer perimeter of the second 104 and the third dies 506 and provides fluid communication for the heat pipe 108 between the passages of the heat pipe element 502 and an expansion chamber 510 in an upper cooling element 512 disposed over the third die 506, such that the heat pipe 108 is a completed and sealed loop. In some embodiments, vacuum pulling can be implemented (e.g., in the expansion chamber and/or in the channels) during the sealing for performance improvement. A second dummy die 514 is additionally disposed over the first die 102 adjacent the outer perimeter of the second 104 and the third dies 506 and provides fluid communication for the heat pipe 108 between passages of the heat pipe element 502 and the expansion chamber 510 disposed over the third die 506. The portions of the heat pipe 108 extending through one or more dummy dies 508, 514 and the expansion chamber or cavity 510 can be fabricated using a similar approach to the one used in fabricating the heat pipe element 106 as shown in FIGS. 3A-3G. The dummy dies 508, 514 can comprise silicon or other suitable materials. In such a configuration, the heat pipe 108 can be configured to have a first portion 516 extending through the first dummy die 508, a second portion 518 extending through the heat pipe element, a third portion 522 extending through the second dummy die 514, and a fourth portion 524 (e.g., the expansion chamber 510) extending through the upper cooling element 512. Gaps 528 are shown in the illustrated embodiment between the stacked dies 104, 506 disposed over the second portion 518 of the heat pipe 108 and the first and the second dummy dies 508, 514. In some embodiments, this gap 528 can be filled using any suitable material, as is known in the art.

In some embodiments, when the liquid within the heat pipe element 502 is heated and transitions to a vapor, the vapor can be transported through the first or the third portions 516, 522 of the heat pipe 108, extending through the first or second dummy dies 508, 514. In some embodiments, the vapor can be transported through both the first and the third portions 516, 522 of the heat pipe 108 as indicated by the arrows illustrating the flow path of the heated vapor. In some embodiments, the expansion chamber 510 comprises a condensing or cool zone of the heat pipe 108. In the expansion chamber 510, the vapor is cooled, with the thermal energy being transferred away from the stacked assembly 500 through a heat dissipation element such as a heat sink or heat spreader 504. The vapor undergoes the phase change back to a liquid and travels to the second portion 518 of the heat pipe 108 through the first and/or third portions 516, 522 of the heat pipe 108 extending through the first/second dummy dies 508, 514 along the wicking layer or surface 114 that lines the heat pipe through capillary action. In some embodiments, a heat sink 504 is positioned over the expansion chamber 510 of the die stack assembly 500. In some embodiments, the heat sink 504 is directly bonded to the upper cooling element 512. In some embodiments, a TIM 530 is formed (e.g., deposited) onto the upper surface 532 of the upper cooling element (e.g., expansion chamber element) 512 and a heat sink 504 is disposed over the TIM 530.

In other arrangements, a continuous dummy frame can surround the second and third dies and provide the fluid communication between the heat pipe element between dies and the upper expansion chamber. In still other arrangements, the dummy element(s) housing vertical channels can also extend adjacent the heat pipe element and can include a bend to communicate with the passages of the heat pipe element, and similarly the dummy element(s) can extend upward adjacent the upper cooling element and can include bends to communicate with the expansion chamber. The skilled artisan will appreciate that other techniques can be employed to fluidly connect the heat pipe segments of the heat pipe element and the expansion chamber of the upper cooling element and complete the circuit or loop of the heat pipe.

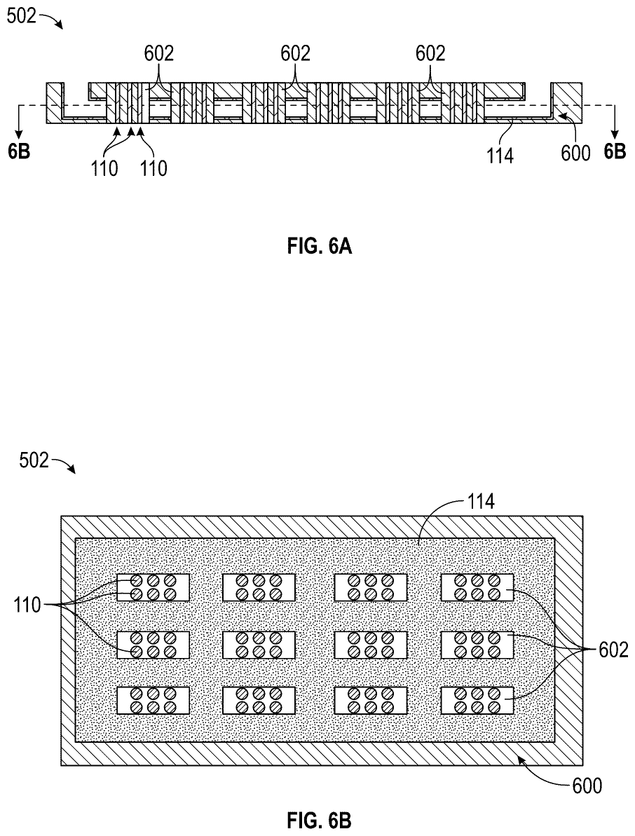

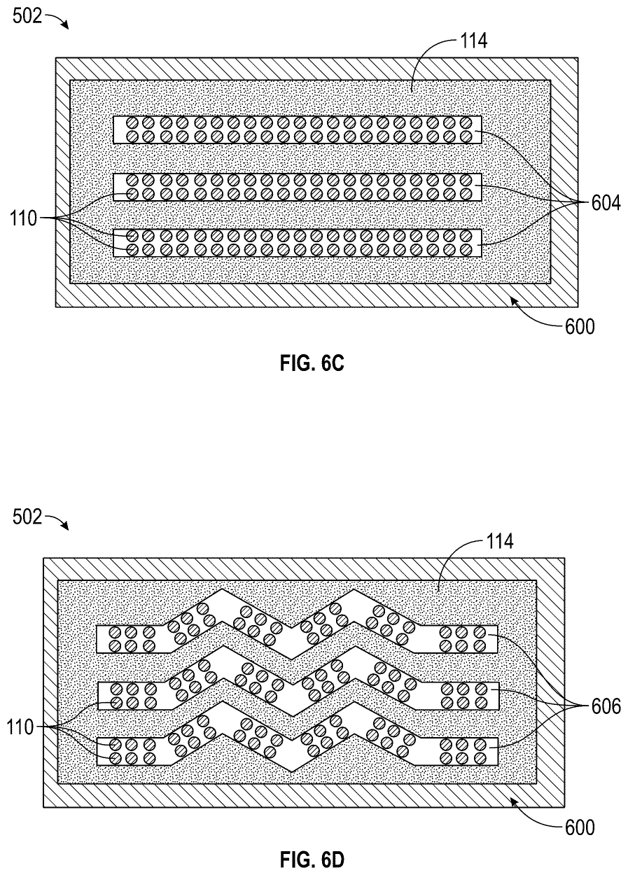

FIG. 6A illustrates a schematic side sectional view of the heat pipe element 502 of FIG. 5. In some embodiments, the cavity 600 can be lined with a wicking material 114. A plurality of TSVs 110 is provided that extends through pillar or wall structures 602 in the cooling element layer 502. Because of the properties of the heat pipe element 502 (e.g., a heat pipe element fabricated from directly bonded substrate materials and integrated between dies in an integrated die stack), the heat pipe element 502 can be flexibly designed to have various configurations as needed for various applications. For example, the heat pipe element 502 can comprise a single open cavity 600 having a plurality of pillars 602 extending through the cavity, such that the plurality of pillars are conduits for the plurality of TSVs 110 to extend through. In another example, the heat pipe element 502 can comprise multiple cavities or channels 600 having a plurality of walls or wall structures that extend along a length of the heat pipe element and are parallel to the multiple cavities or channels. These walls or wall structures also act as conduits for the plurality of TSVs 110 to extend through. Such alternative configurations will be described in more detail.

FIG. 6B is a top view of one variant of the heat pipe element 502 taken along the 6B-6B line in FIG. 6A. In FIG. 6B, the heat pipe element 502 is fabricated to include a plurality of pillars or pillar-like structures 602 that traverse the heat pipe element 502. The pillars 602 provide a material (e.g., single-crystal silicon) through which TSVs 110 can extend, facilitating the electrical connection of elements below and above the heat pipe element 502. The pillars 602 can be arranged to have a pattern with regular spacing, as shown in FIG. 6B. In some embodiments, the pillars 602 can be positioned with irregular spacing. Surrounding the pillars 602 is an open cavity 600 of the heat pipe element 502, which further includes the wicking layer 114, such that the cavity can serve as a segment of the heat pipe 108 (see FIG. 5). In some embodiments, and as shown in FIG. 6C, the structures through which the TSVs 110 extend can include walls or wall-like structures 604. In FIG. 6C, three wall-like structures 604 extend along the length of the heat pipe element 502, having a plurality of TSVs 110. The walls 604 divide the cavity 600 into channels which can serve as segments of the heat pipe 108 (FIG. 5). The plurality of TSVs 110 can be formed within the walls 604 in a periodic or regular pattern, or they can be formed within the walls 604 in an irregular pattern. The pitch of the TSVs is fine and can be approximately 1 μm to 200 μm. FIG. 6D illustrates an embodiment where the wall-like structures 606 can comprise a serpentine or other complex pattern, the walls 606 dividing the cavity into channels which can serve as segments of the heat pipe 108. In some embodiments, the overall volume of passage through a heat pipe element 502 comprising a single open cavity can be approximately the same as or similar to the overall volume of passage through a heat pipe element 502 comprising multiple channels. In some embodiments, a heat pipe element comprising multiple channels can include channels having a width that is approximately the same in size as the width of the pillars or walls/wall-like structures through which the TSVs extend.

Such configurations are possible with the heat pipe approach as compared to a liquid channel approach. The liquid channel approach requires high pressures to maintain sufficient liquid flow for heat dissipation, which would require voluminous channels that could not be accommodated in the thin cooling element taught herein, and would further create challenges for lengthy, resistive interconnects, and limitations on their pitch, through elements thick enough to accommodate liquid cooling channels. The heat pipe approach enables much smaller passages (cavities or channels) in the cooling element between dies. Although three configurations have been illustrated, the skilled artisan will appreciate that due to the flexibility provided by semiconductor processing techniques, including hybrid bonding, to define solid state elements with cavities lined with wicking material, other configurations of such cavity-defining structures through which TSVs extend can be provided.

### Examples of Direct Bonding Methods and Directly Bonded Structures

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 708a and/or 708b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

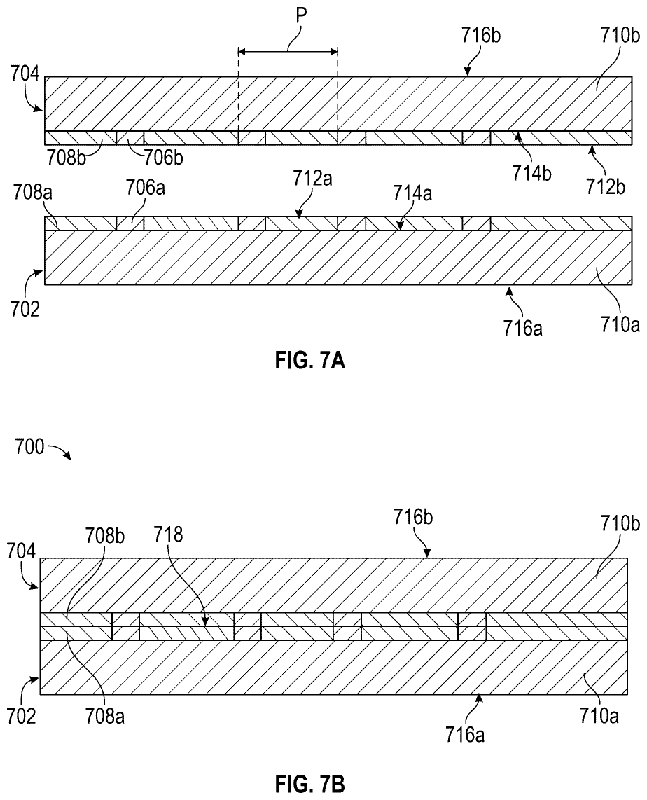

FIGS. 7A and 7B schematically illustrate cross-sectional side views of first and second elements 702, 704 prior to and after, respectively, a process for forming a directly bonded structure, and more particularly a hybrid bonded structure, according to some embodiments. In FIG. 7B, a bonded structure 700 comprises the first and second elements 702 and 704 that are directly bonded to one another at a bond interface 718 without an intervening adhesive. Conductive features 706a of a first element 702 may be electrically connected to corresponding conductive features 706b of a second element 704. In the illustrated hybrid bonded structure 700, the conductive features 706a are directly bonded to the corresponding conductive features 706b without intervening solder or conductive adhesive.

The conductive features 706a and 706b of the illustrated embodiment are embedded in, and can be considered part of, a first bonding layer 708a of the first element 702 and a second bonding layer 708b of the second element 704, respectively. Field regions of the bonding layers 708a, 708b extend between and partially or fully surround the conductive features 706a, 706b. The bonding layers 708a, 708b can comprise layers of non-conductive materials suitable for direct bonding, as described above, and the field regions are directly bonded to one another without an adhesive. The non-conductive bonding layers 708a, 708b can be disposed on respective front sides 714a, 714b of base substrate portions 710a, 710b.

The first and second elements 702, 704 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 702, 704, and back-end-of-line (BEOL) interconnect layers over such semiconductor portions. The bonding layers 708a, 708b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 710a, 710b, and can electrically communicate with at least some of the conductive features 706a, 706b. Active devices and/or circuitry can be disposed at or near the front sides 714a, 714b of the base substrate portions 710a, 710b, and/or at or near opposite backsides 716a, 716b of the base substrate portions 710a, 710b. In other embodiments, the base substrate portions 710a, 710b may not include active circuitry, but may instead comprise dummy substrates, passive interposers, passive optical elements (e.g., glass substrates, gratings, lenses), etc. The bonding layers 708a, 708b are shown as being provided on the front sides of the elements, but similar bonding layers can be additionally or alternatively provided on the back sides of the elements.

In some embodiments, the base substrate portions 710a, 710b can have significantly different coefficients of thermal expansion (CTEs), and bonding elements that include such different based substrate portions can form a heterogenous bonded structure. The CTE difference between the base substrate portions 710a and 710b, and particularly between bulk semiconductor (typically single crystal) portions of the base substrate portions 710a, 710b, can be greater than 5 ppm/° C. or greater than 10 ppm/° C. For example, the CTE difference between the base substrate portions 710a and 710b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 710a, 710b can comprise optoelectronic single crystal materials, including perovskite materials, that are useful for optical piezoelectric or pyroelectric applications, and the other of the base substrate portions 710a, 710b comprises a more conventional substrate material. For example, one of the base substrate portions 710a, 710b comprises lithium tantalate (LiTaO3) or lithium niobate (LiNbO3), and the other one of the base substrate portions 710a, 710b comprises silicon (Si), quartz, fused silica glass, sapphire, or a glass. In other embodiments, one of the base substrate portions 710a, 710b comprises a III-V single semiconductor material, such as gallium arsenide (GaAs) or gallium nitride (GaN), and the other one of the base substrate portions 710a, 710b can comprise a non-III-V semiconductor material, such as silicon (Si), or can comprise other materials with similar CTE, such as quartz, fused silica glass, sapphire, or a glass. In still other embodiments, one of the base substrate portions 710a, 710b comprises a semiconductor material and the other of the base substrate portions 710a, 710b comprises a packaging material, such as a glass, organic or ceramic substrate.

In some arrangements, the first element 702 can comprise a singulated element, such as a singulated integrated device die. In other arrangements, the first element 702 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 704 can comprise a singulated element, such as a singulated integrated device die. In other arrangements, the second element 704 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 702, 704 are shown, any suitable number of elements can be stacked in the bonded structure 700. For example, a third element (not shown) can be stacked on the second element 704, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 702. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 708a, 708b, the bonding layers 708a, 708b can be prepared for direct bonding. Non-conductive bonding surfaces 712a, 712b at the upper or exterior surfaces of the bonding layers 708a, 708b can be prepared for direct bonding by polishing, for example, by CMP. The roughness of the polished bonding surfaces 712a, 712b can be less than 30 Å rms. For example, the roughness of the bonding surfaces 712a and 712b can be in a range of about 0.1 Å rms to 15 Å rms, 0.5 Å rms to 10 Å rms, or 1 Å rms to 5 Å rms. Polishing can also be tuned to leave the conductive features 706a, 706b recessed relative to the field regions of the bonding layers 708a, 708b.

Preparation for direct bonding can also include cleaning and exposing one or both of the bonding surfaces 712a, 712b to a plasma and/or etchants to activate at least one of the surfaces 712a, 712b. In some embodiments, one or both of the surfaces 712a, 712b can be terminated with a species after activation or during activation (e.g., during the plasma and/or etch processes). Without being limited by theory, in some embodiments, the activation process can be performed to break chemical bonds at the bonding surface(s) 712a, 712b, and the termination process can provide additional chemical species at the bonding surface(s) 712a, 712b that alters the chemical bond and/or improves the bonding energy during direct bonding. In some embodiments, the activation and termination are provided in the same step, e.g., a plasma to activate and terminate the surface(s) 712a, 712b. In other embodiments, one or both of the bonding surfaces 712a, 712b can be terminated in a separate treatment to provide the additional species for direct bonding. In various embodiments, the terminating species can comprise nitrogen. For example, in some embodiments, the bonding surface(s) 712a, 712b can be exposed to a nitrogen-containing plasma. Other terminating species can be suitable for improving bonding energy, depending upon the materials of the bonding surfaces 712a, 712b. Further, in some embodiments, the bonding surface(s) 712a, 712b can be exposed to fluorine. For example, there may be one or multiple fluorine concentration peaks at or near a bond interface 718 between the first and second elements 702, 704. Typically, fluorine concentration peaks occur at interfaces between material layers. Additional examples of activation and/or termination treatments may be found in U.S. Pat. Nos. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 700, the bond interface 718 between two non-conductive materials (e.g., the bonding layers 708a, 708b) can comprise a very smooth interface with higher nitrogen (or other terminating species) content and/or fluorine concentration peaks at the bond interface 718. In some embodiments, the nitrogen and/or fluorine concentration peaks may be detected using various types of inspection techniques, such as SIMS techniques. The polished bonding surfaces 712a and 712b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 708a and 708b can be directly bonded to one another without an adhesive. In some embodiments, the elements 702, 704 are brought together at room temperature, without the need for application of a voltage, and without the need for application of external pressure or force beyond that used to initiate contact between the two elements 702, 704. Contact alone can cause direct bonding between the non-conductive surfaces of the bonding layers 708a, 708b (e.g., covalent dielectric bonding). Subsequent annealing of the bonded structure 700 can cause the conductive features 706a, 706b to directly bond.

In some embodiments, prior to direct bonding, the conductive features 706a, 706b are recessed relative to the surrounding field regions, such that a total gap between opposing contacts after dielectric bonding and prior to anneal is less than 15 nm, or less than 10 nm. Because the recess depths for the conductive features 706a and 706b can vary across each element, due to process variation, the noted gap can represent a maximum or an average gap between corresponding conductive features 706a, 706b of two joined elements (prior to anneal). Upon annealing, the conductive features 706a and 706b can expand and contact one another to form a metal-to-metal direct bond.

During annealing, the conductive features 706a, 706b (e.g., metallic material) can expand while the direct bonds between surrounding non-conductive materials of the bonding layers 708a, 708b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 706a, 706b can comprise discrete pads, contacts, electrodes, or traces at least partially embedded in the non-conductive field regions of the bonding layers 708a, 708b. In some embodiments, the conductive features 706a, 706b can comprise exposed contact surfaces of TSVs (e.g., through silicon vias).

As noted above, in some embodiments, in the elements 702, 704 of FIG. 7A prior to direct bonding, portions of the respective conductive features 706a and 706b can be recessed below the non-conductive bonding surfaces 712a and 712b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 706a, 706b or to average depths of the recesses relative to local non-conductive field regions. Even for an individual conductive feature 706a, 706b, the vertical recess can vary across the feature, and so can be measured at or near the lateral middle or center of the cavity in which a given conductive feature 706a, 706b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 706a, 706b across the direct bond interface 718 (e.g., small or fine pitches for regular arrays).

In some embodiments, a pitch p of the conductive features 706a, 706b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 706a and 706b to one of the lateral dimensions (e.g., a diameter) of the bonding pad is less than 20, or less than 10, or less than 5, or less than 3 and sometimes desirably less than 2. In various embodiments, the conductive features 706a and 706b and/or traces can comprise copper or copper alloys, although other metals may be suitable, such as nickel, aluminum, or alloys thereof. The conductive features disclosed herein, such as the conductive features 706a and 706b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 702, 704, as shown, the orientations of one or more conductive features 706a, 706b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 706b in the bonding layer 708b (and/or at least one internal conductive feature, such as a BEOL feature) of the upper element 704 may be tapered or narrowed upwardly, away from the bonding surface 712b. By way of contrast, at least one conductive feature 706a in the bonding layer 708a (and/or at least one internal conductive feature, such as a BEOL feature) of the lower element 702 may be tapered or narrowed downwardly, away from the bonding surface 712a. Similarly, any bonding layers (not shown) on the backsides 716a, 716b of the elements 702, 704 may taper or narrow away from the backsides, with an opposite taper orientation relative to front side conductive features 706a, 706b of the same element.

As described above, in an anneal phase of hybrid bonding, the conductive features 706a, 706b can expand and contact one another to form a metal-to-metal direct bond. In some embodiments, the materials of the conductive features 706a, 706b of opposite elements 702, 704 can interdiffuse during the annealing process. In some embodiments, metal grains grow into each other across the bond interface 718. In some embodiments, the metal is or includes copper, which can have grains oriented along the 111 crystal plane for improved copper diffusion across the bond interface 718. In some embodiments, the conductive features 706a and 706b may include nanotwinned copper grain structure, which can aid in merging the conductive features during anneal. There is substantially no gap between the non-conductive bonding layers 708a and 708b at or near the bonded conductive features 706a and 706b. In some embodiments, a barrier layer may be provided under and/or laterally surrounding the conductive features 706a and 706b (e.g., which may include copper). In other embodiments, however, there may be no barrier layer under the conductive features 706a and 706b.

In one aspect, the techniques described herein relate to an electronics package including: a first die. A cooling element is disposed over the first die. The cooling element comprises at least one cavity having a wicking layer disposed over an interior surface of the at least one cavity. A second die is disposed over the cooling element; with a plurality of vias extending through the cooling element from the first die to the second die.

In some embodiments, the cooling element comprises a first substrate and a second substrate. In some embodiments, the first substrate is directly bonded to the second substrate. In some embodiments, the first substrate includes a first material and the second substrate includes a second material, where the first material is different than the second material.

In some embodiments, the cooling element includes two or more cavities, wherein the two or more cavities are separated by one or more wall structures extending along a length of the cooling element and extending from a bottom surface of the cooling element to a top surface of the cooling element. In some embodiments, the vias extend through the one or more wall structures and electrically connects the first and second dies. In some embodiments, the one or more wall structures are serpentine.

In some embodiments, the wicking layer includes a non-smooth interior surface of the at least one cavity. In some embodiments, the wicking layer includes a dendritic material.

In some embodiments, the vias have a pitch in a range of 1 μm to 200 μm.

In some embodiments, the electronics package also includes at least one dummy die having a connecting cavity in fluid communication with the at least one cavity of the cooling element.

In some embodiments, the electronics package also includes an upper cooling element over the second die. The upper cooling element includes an expansion chamber in fluid communication with the second cavity.

In some embodiments, the electronics package also includes a heat sink disposed over and coupled to the upper cooling element.

In some embodiments, a cross-sectional shape of the first cavity is approximately hexagonal.

In some embodiments, the cooling element includes an open cavity having one or more pillar structures extending through the cooling element. In some embodiments, the vias extend through the pillar structures and electrically connect the first and the second dies.

In some embodiments, the cavity includes a fluid. In some embodiments, the fluid evaporates at a temperature between approximately 50° C. and approximately 150° C. In some embodiments, the fluid is a phase change fluid.

In another aspect, the techniques described herein relate to a stacked assembly including: a first microelectronic element and a second microelectronic element. A first dummy die is disposed over the first microelectronic element. A heat pipe is disposed over and approximately parallel to the first microelectronic element. The heat pipe has a first portion, and a second portion, where the first portion extends through the first dummy die and the second portion is disposed over and approximately parallel to the first microelectronic element. The stacked assembly also includes a plurality of electrically conductive vias for communicating signals from the first microelectronic element to the second microelectronic element, where the second microelectronic element is disposed over the heat pipe.

In some embodiments, the heat pipe includes a casing structure. In some embodiments, the casing structure includes a non-metal material. In some embodiments, the casing structure includes silicon.

In some embodiments, the heat pipe includes a first wicking layer on a first interior surface of the heat pipe.

In some embodiments, the stacked assembly also includes a second dummy die disposed over the first microelectronic element and a third portion of the heat pipe, wherein the third portion extends through the second dummy die. In some embodiments, the heat pipe includes a fourth portion disposed over and approximately parallel to the second element, where the fourth portion is coupled to the first portion and the third portion of the heat pipe. In some embodiments, the stacked assembly also includes a heat sink disposed over the fourth portion, where the heat sink is in thermal communication with the fourth portion.

In some embodiments, the stacked assembly also includes one or more wall structures approximately parallel to the heat pipe and extending from the first element to the second element. The electrically conductive vias extend through the one or more wall structures and electrically connect the first and the second microelectronic elements. In some embodiments, one or more pillar structures extend from the first microelectronic element to the second microelectronic element. The electrically conductive vias extend through the pillar structures and electrically connect the first and the second microelectronic elements.

In some embodiments, the electrically conductive vias have a pitch in a range of 1 μm to 200 μm.

In some embodiments, the heat pipe includes a phase change fluid.

In some embodiments, the heat pipe includes a fluid having a boiling point in a range of approximately 50° C. and approximately 150° C.

In another aspect, the techniques described herein relate to a method of forming a microelectronic stack including a cooling structure. The method includes etching a first trench in a first substrate and a second trench in a second substrate. A first wicking layer is formed in the first trench and a second wicking layer is formed in the second trench. The first substrate is bonded to the second substrate at a bonding interface such that the first trench and the second trench together define a portion of a heat pipe.

In some embodiments, the method also includes forming a plurality of first vias in the first substrate and a plurality of second vias in the second substrate prior to bonding. The first substrate is bonded to the second substrate by hybrid bonding such that the first vias electrically and mechanically connect with the second vias and the first substrate directly bonds to the second substrate at the bonding interface.

In some embodiments, the method also includes planarizing a first surface of the first substrate and exposing end portions of the plurality of first vias. The first surface of the first substrate is hybrid bonded to a first die after planarizing the first surface. A second surface of the second substrate is planarized, and end portions of the second vias are exposed. The second surface of the second substrate is hybrid bonded to a second die.

In some embodiments, forming the first and the second wicking layers includes etching to texture a first interior surface of the first trench and a second interior surface of the second trench.

In some embodiments, forming the first and the second wicking layers includes growing a wicking material on a first interior surface of the first trench and a second interior surface of the second trench.

In some embodiments, forming the first and the second wicking layers includes depositing a wicking material on a first interior surface of the first trench and a second interior surface of the second trench.

In another aspect, the techniques described herein relate to a heat pipe device including. The heat pipe device includes a first substrate having a first bonding surface and a second substrate having a second bonding surface. The first bonding surface and the second bonding surface are directly bonded. The first substrate includes at least a first trench, where the first trench of the first substrate and the second substrate are coupled and form a cavity. A wicking layer is disposed over a surface of the cavity.

In some embodiments, the second substrate includes at least a second trench in the second substrate, where the first and the second trenches are coupled and form the cavity.

In some embodiments, the heat pipe device also includes first interconnects in the first substrate and second interconnects in the second substrate, where the first and the second interconnects are directly bonded. The first and the second interconnects can be hybrid bonded and include through substrate vias.

In some embodiments, the heat pipe device also includes one or more structural elements extending along a length of the wicking cavity device and extending from a bottom surface of the heat pipe device to a top surface of the heat pipe device. The first and the second interconnects are formed in the one or more structural elements.

In some embodiments, the heat pipe device also includes one or more pillar structures extending through the heat pipe device. The first and the second plurality of interconnects are formed in the pillar structures.

In some embodiments, the heat pipe device also includes a first planarized surface opposite the first bonding surface of the first substrate and a second planarized surface opposite the second bonding surface of the second substrate.

In some embodiments, the techniques described herein relate to a die stack including the heat pipe device. The die stack includes: a first active die disposed below the heat pipe device; a second active die disposed over the heat pipe device; and a heat dissipation element disposed over the second active die and coupled to the heat pipe device. In some embodiments, the first and the second interconnects electrically connect the first and the second active dies. In some embodiments, the first active die is hybrid bonded to the heat pipe device, and the second active die is hybrid bonded to the heat pipe device.

In some embodiments, the heat pipe device has a thickness of approximately 50 μm or less.

In some embodiments, the wicking layer is a dendritic material. In some embodiments, the wicking layer includes an etched surface of the cavity having a roughness greater than approximately 0.5 μm.

In some embodiments, the first and second substrates comprise silicon.

In another aspect, the techniques described herein relate to a heat pipe device including a phase change fluid and a monolithic structure having at least one cavity housing the phase change fluid. The monolithic structure is configured to be disposed over a first die and below a second die.

In some embodiments, the monolithic structure includes silicon.

In some embodiments, the heat pipe device also includes a plurality of interconnects extending through the monolithic structure and electrically connecting the first die and the second die. In some embodiments, the interconnects are through substrate vias. In some embodiments, the interconnects include a group having a pitch of approximately 1 μm to 200 μm.

In some embodiments, the heat pipe device also includes one cavity and one or more pillar structures extending through the cavity. At least some interconnects are formed in the one or more pillar structures.

In some embodiments, a portion of the heat pipe device that is configured to be disposed over the first die and below the second die has a thickness of approximately 50 μm or less.

In some embodiments, the heat pipe device also includes a wicking layer disposed over an interior surface of the at least one cavity. In some embodiments, the wicking layer is a dendritic material. In some embodiments, the wicking layer includes an etched surface of the at least one cavity having a roughness greater than approximately 0.5 μm.

In some embodiments, the heat pipe device also includes two or more cavities and one or more wall structures extending along a length of the heat pipe device. The one or more wall structures extend from a bottom surface of the heat pipe device to a top surface of the heat pipe device.

In another aspect, the techniques described herein relate to an electronics package including a first die, a semiconductor element disposed over the first die and including at least one cavity, a second die disposed over the semiconductor element, and a plurality of vias extending through the semiconductor element from the first die to the second die.

In some embodiments, the semiconductor element is a cooling element. In some embodiments, the cooling element includes the cavity having a wicking layer disposed over an interior surface of the cavity. In some embodiments, the wicking layer includes at least one of a metal fiber, a porous metal, a wire mesh, a glass fiber, a woven cloth, or a composite wicking media. In some embodiments, the wicking layer is a metal fiber that includes at least one of copper, aluminum, nickel, stainless steel, titanium, or a metal alloy.

In some embodiments, the cooling element includes a first substrate and a second substrate. In some embodiments, the electronics package also includes a hybrid bond between the first substrate and the second substrate. In some embodiments, the cooling element includes two or more cavities separated by one or more wall structures extending along a length of the cooling element and extending from a bottom surface of the cooling element to a top surface of the cooling element.

In some embodiments, the vias have a pitch in a range of 1 μm to 200 μm.

In some embodiments, the at least one cavity includes a liquid configured to evaporate at a temperature between approximately 50° C. and approximately 150° C.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. An electronics package comprising:
a first die;
a cooling element disposed over the first die, the cooling element comprising at least one cavity having a wicking layer disposed over an interior surface of the at least one cavity;
a second die disposed over the cooling element; and
a plurality of vias extending through the cooling element from the first die to the second die.

2. The electronics package of claim 1, wherein the cooling element comprises a first substrate and a second substrate, and wherein the first substrate is directly bonded to the second substrate.

3. (canceled)

4. (canceled)

5. The electronics package of claim 1, wherein the cooling element comprises two or more cavities, wherein the two or more cavities are separated by one or more wall structures extending along a length of the cooling element and extending from a bottom surface of the cooling element to a top surface of the cooling element, and wherein the plurality of vias extends through the one or more wall structures and electrically connects the first and second dies.

6. (canceled)

7. (canceled)

8. (canceled)

9. (canceled)

10. The electronics package of claim 1, wherein the plurality of vias have a pitch in a range of 1 μm to 200 μm.

11. The electronics package of claim 1, further comprising at least one dummy die comprising a connecting cavity in fluid communication with the at least one cavity of the cooling element.

12. The electronics package of claim 11, further comprising an upper cooling element over the second die, the upper cooling element including an expansion chamber in fluid communication with the connecting cavity.

13. The electronics package of claim 12, further comprising a heat sink disposed over and coupled to the upper cooling element.

14. (canceled)

15. The electronics package of claim 1, wherein the cooling element comprises one open cavity having one or more pillar structures extending through the cooling element, wherein the plurality of vias extends through the pillar structures and electrically connects the first and second dies.

16. (canceled)

17. The electronics package of claim 1, wherein the at least one cavity comprises a fluid having a boiling point in a range of approximately 50° C. and approximately 150° C.

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. A heat pipe device comprising:
a phase change fluid; and
a monolithic structure having at least one cavity housing the phase change fluid, wherein the monolithic structure is disposed over a first die and below a second die.

54. The heat pipe device of claim 53, wherein the monolithic structure comprises silicon.

55. The heat pipe device of claim 53, further comprising a plurality of interconnects extending through the monolithic structure and electrically connecting the first die and the second die.

56. (canceled)

57. (canceled)

58. (canceled)

59. The heat pipe device of claim 53, wherein a portion of the heat pipe device disposed over the first die and below the second die has a thickness of approximately 50 μm or less.

60. The heat pipe device of claim 53, further comprising a wicking layer disposed over an interior surface of the at least one cavity.

61. (canceled)

62. (canceled)

63. (canceled)

64. An electronics package comprising:
a first die;
a semiconductor element disposed over the first die, the semiconductor element comprising at least one cavity;
a second die disposed over the semiconductor element; and
a plurality of vias extending through the semiconductor element from the first die to the second die.

65. The electronics package of claim 64, wherein the semiconductor element is a cooling element.

66. The electronics package of claim 65, wherein the cooling element comprises the at least one cavity having a wicking layer disposed over an interior surface of the at least one cavity.

67. (canceled)

68. (canceled)

69. The electronics package of claim 65, wherein the cooling element comprises a first substrate and a second substrate.

70. The electronics package of claim 69, further comprising a hybrid bond, wherein the hybrid bond is between the first substrate and the second substrate.

71. The electronics package of claim 65, wherein the cooling element comprises two or more cavities, wherein the two or more cavities are separated by one or more wall structures extending along a length of the cooling element and extending from a bottom surface of the cooling element to a top surface of the cooling element.

72. (canceled)

73. (canceled)
